(19) United States
(12) Patent Application Publication
(10) Pub. No.: US 2025/0389595 A1
(43) Pub. Date: Dec. 25, 2025

(54) GALLIUM NITRIDE TEMPERATURE SENSOR

(71) Applicant: Analog Devices, Inc., Wilmington, MA (US)

(72) Inventors: Pradeep Kumar Chandrasekar, Woburn, MA (US); Brett A. Miwa, Wellesley, MA (US)

(21) Appl. No.: 18/747,747

(22) Filed: Jun. 19, 2024

(51) Int. Cl. G01K 7/21; H01L 23/34; H01L 29/778

(52) U.S. Cl. CPC G01K 7/21; H01L 23/34; H10D 30/475

(57) ABSTRACT

A temperature sensor circuit includes a gallium nitride (GaN) integrated circuit (IC) die including a temperature sensitive two-dimensional electron gas (2DEG) resistive circuit element that includes a 2DEG channel; and a sensing circuit included to sense resistance of the temperature sensitive 2DEG resistive circuit element.

### FIELD OF THE DISCLOSURE

This document pertains generally, but not by way of limitation, to temperature sensor circuits that can be used to monitor operation of power switching devices in circuits, such as switching power converters for example.

### BACKGROUND

Switching power converter circuits can be used to produce power at an output voltage from an input having a different voltage. The converter circuits may operate to recurrently charge a magnetic circuit element, such as an inductor, from an energy source and then discharge the energy of the magnetic circuit element to drive a load. The charging and discharging can be accomplished using electronic switching devices that include field effect transistors (FETs). It is desired for the power conversion of the power converter circuits to be efficient especially for applications in electric vehicles and industrial infrastructure. One way to improve efficiency is to use wide bandgap devices as the switching devices. Wide bandgap devices can handle higher voltage and power levels, can be much smaller than silicon FETs for a given power level, and can operate with much higher efficiency. However, there can be challenges in using wide bandgap devices in switching power converter circuits.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a circuit diagram of an example of portions of a switching converter circuit.

FIG. 2 is a circuit diagram of an example of a temperature sensor circuit.

FIG. 3 shows illustrations of a two-dimensional electron gas (2DEG) resistor having a 2DEG channel.

FIG. 4 is an illustration of a high electron mobility transistor (HEMT) having a 2DEG channel.

FIG. 5 is a diagram of an example of a circuit to trim for process variation in resistance of a 2DEG channel.

FIG. 6 is a circuit diagram of another example of a temperature sensor circuit.

FIG. 7 is a flow diagram of a method of monitoring temperature of a switching circuit element of a switching regulator circuit.

### DETAILED DESCRIPTION

As explained previously herein, it is desired to operate switching power converter circuits efficiently. Using wide bandgap transistors for the switching power devices in switching power converter circuits can materially improve efficiency of the switching power converter circuits. One type of wide bandgap device is a gallium nitride high electron mobility transistor (GaN HEMT). GaN devices can be switched faster without sacrificing conversion efficiency, compared to the high voltage silicon devices, such as field effect transistors (FETs) or insulated gate bipolar transistors (IGBTs), that are typically used in switching power converters. GaN HEMTs can handle higher voltage and power levels, are much smaller for a given power level, and can operate with much higher efficiency, compared to their silicon alternatives.

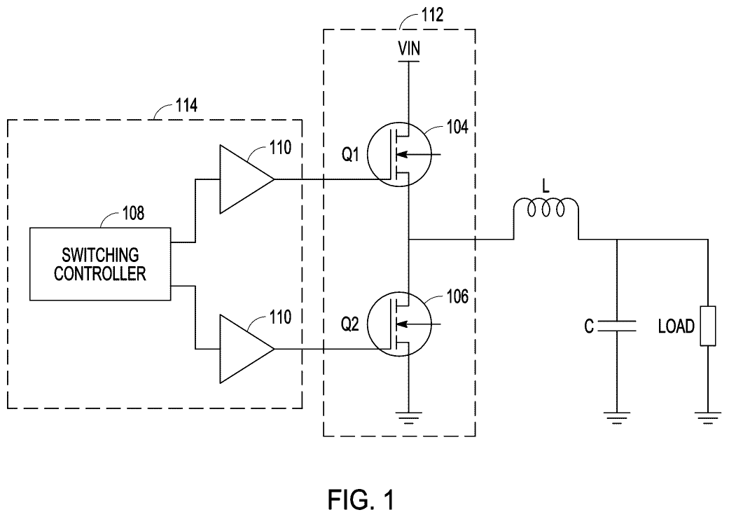

FIG. 1 is a circuit diagram of an example of portions of a switching converter circuit 102. The switching converter circuit 102 includes two GaN power devices; a top HEMT 104 and a bottom HEMT 106. The switching of the HEMTs charges the inductor (L) and the inductor discharges energy into the LOAD. The circuit diagram also includes a switching controller 108 that may provide pulse width modulation (PWM) control for the switching of the HEMTs. The circuit also includes gate drivers 110 to provide drive signals to the HEMTs. The HEMTs are included in a GaN integrated circuit (IC) die 112. The switching controller 108 and the gate drivers may be complementary metal oxide semiconductor (CMOS) devices that are included in a CMOS IC die 114.

The GaN HEMTs have superior performance over silicon metal oxide semiconductor FETs (MOSFETs) in terms of lower gate capacitance and lower on-resistance for the same area. Using the GaN HEMTs improves the efficiency of the switching converter circuit 102 and supports higher switching frequencies that can reduce the size of the inductor and the overall size of the switching converter circuit 102. Like silicon MOSFETs, GaN HEMTs dissipate power when switching, and may heat up quickly. It is beneficial for the junction temperature of the GaN HEMTs to be measured accurately to enable protection of the HEMTs from overheating and failing.

Temperature sensor circuits may be used to monitor temperature, but the temperature sensing circuits typically include a bipolar junction transistor (BJT) or bipolar diode, which are used to produce a proportional-to-absolute-temperature (PTAT) current signal or counter-to-absolute-temperature (CTAT) voltage signal. These temperature-dependent signals are then compared against a fixed current or voltage to determine device temperature. One challenge with GaN HEMT switches is that their manufacturing processes typically do not include BJT or diode components. In one solution to the lack of BJT or diode on the GaN HEMT device, the temperature of the GaN HEMTs in FIG. 1 may be estimated by including the temperature sensor circuit in the CMOS IC die 114 and placing the CMOS IC die 114 near the GaN IC die 112. With this solution, the temperature of the GaN IC die 112 may not be measured as accurately as desired.

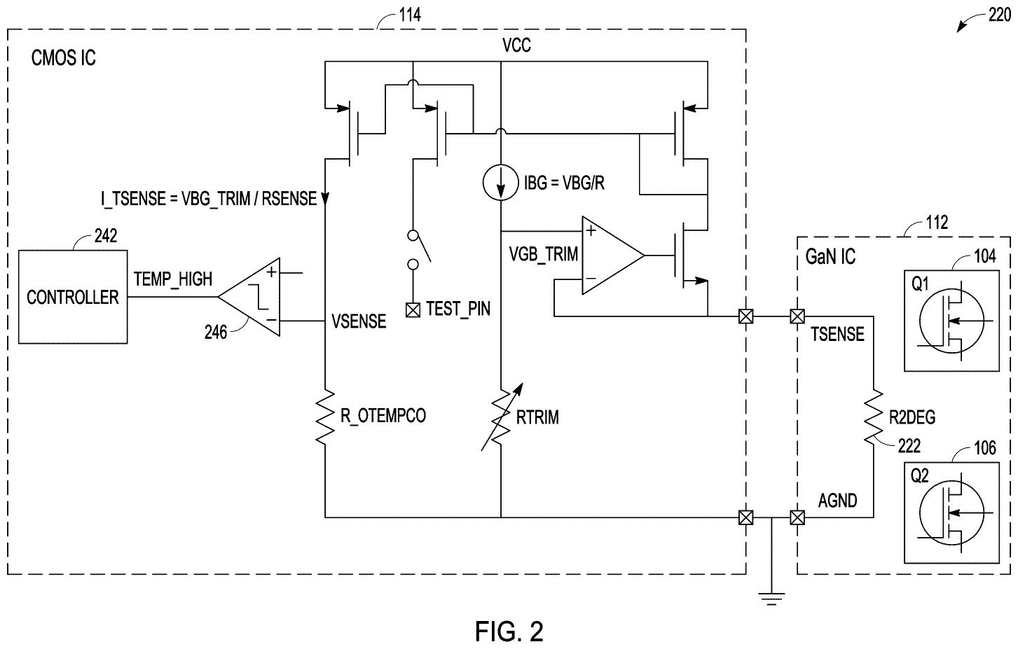

FIG. 2 is a circuit diagram of an example of an improved temperature monitoring circuit 220 to more accurately measure the temperature of GaN power devices in a GaN IC die 112. The temperature sensor circuit 220 includes a temperature sensitive circuit element directly on the GaN IC die 112 (the preferred location) and circuits on another IC die formed using a process that may be different than the GaN IC (e.g., the CMOS IC die 114) to measure the change in the temperature sensitive circuit element due to temperature. In the example of FIG. 2, the temperature sensitive circuit element is a temperature sensitive two-dimensional electron gas (2DEG) resistive circuit element R2DEG resistor 222.

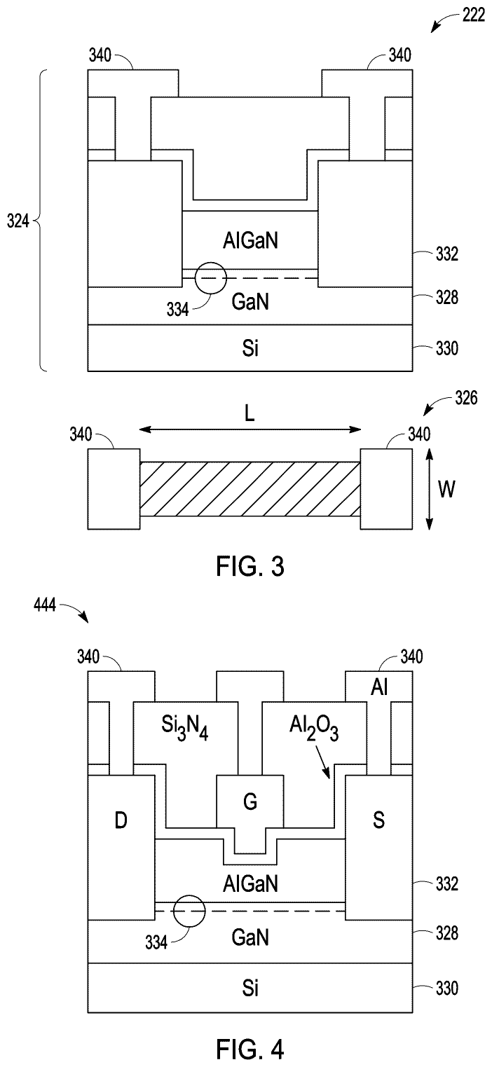

FIG. 3 is a side view 324 and a top view 326 of R2DEG resistor 222. The R2DEG resistor 222 includes a GaN layer 328 on a substrate 330. An aluminum gallium nitride (AlGaN) layer 332 is deposited on the GaN layer 328. An excess of electrons is produced immediately below the AlGaN layer 332 that is referred to as a two-dimensional electron gas (2DEG). The 2DEG forms a very low resistance 2DEG channel for the R2DEG resistor 222. The resistance of the 2DEG channel varies approximately linearly with temperature. The resistance can be measured by applying a known voltage (or current) between the terminals 340 and measuring the resulting current (or voltage) using Ohm's Law. The resistance of the 2DEG channel can be written as

Rsense=R2DEG*(1±Δprocess)*(1+Tempco*T),

where R2DEG is the nominal resistance at nominal temperature, Δprocess is the variation in R2DEG with process, Tempco is the temperature coefficient of the resistance, and T is the temperature elevation above nominal temperature.

Returning to FIG. 2, the separate CMOS IC die 114 includes the sensing circuit to sense the resistance of the R2DEG resistor 222 that is in the GaN IC die 112. The sensing circuit includes a stable zero-temperature coefficient voltage reference such as a bandgap voltage reference that uses the p-n junctions of BJTs to generate a bandgap voltage VBG that is constant with change in temperature.

The stable voltage reference, or a voltage derived from the stable reference, is applied to the R2DEG resistor 222 to generate a temperature sense current I_TSENSE. The CMOS IC die 114 includes a Controller 242 operatively coupled to the sensing circuit. The controller may be a switching controller, such as switching controller 108 of FIG. 1 for example. The sensing circuit may include current mirrors that produce additional currents that match or track the sense current I_TSENSE. In one implementation, a controller 242 monitors the sense current I_TSENSE or a sense voltage VSENSE using a Comparator 246 to detect a high temperature at the power devices of the GaN IC die 112 and may take corrective action such as halting or slowing the switching of the power devices.

The temperature sensitive 2DEG channel used for measurement is a separate circuit element from the HEMT power devices 104 and 106. In some examples, the temperature sensitive 2DEG channel is included in a 2DEG resistor 222. In some examples, the temperature sensitive 2DEG channel is included in a measurement HEMT separate from the power devices. In such cases, the measurement HEMT can be either of the normally-off (enhancement-mode or E-Mode) type or of the normally-on (depletion-mode or D-Mode) type.

FIG. 4 is a side view of an HEMT 444 having a 2DEG channel 334. The HEMT has a drain region (D), source region(S), and a gate region (G). The thermal sensor HEMT 444 may be a D-Mode HEMT, in which case the D-mode HEMT 444 is turned off by applying a negative voltage to the gate. In an alternative, the thermal sensor HEMT 444 can be an E-Mode HEMT, in which case a positive voltage applied to the gate turns the E-Mode HEMT 444 on. The resistance of the 2DEG channel of the measurement HEMT is measured between the terminals 340 connected to the drain and source. Whichever device with a temperature sensitive 2DEG channel is used, the device is preferentially placed close to the power devices to accurately monitor the temperature of the power devices. In cases where the GaN FET is large, or for a GaN IC with two or more GaN FETs integrated on a single GaN die, multiple thermal sensors may be instantiated.

The temperature coefficient of the 2DEG channel is nearly constant for a given manufacturing process, but the nominal value of the resistance can vary between processes and can be controlled by adjusting sensor dimensions. The process variation of the 2DEG channel resistance can be trimmed on the CMOS IC die 114 to achieve greater accuracy.

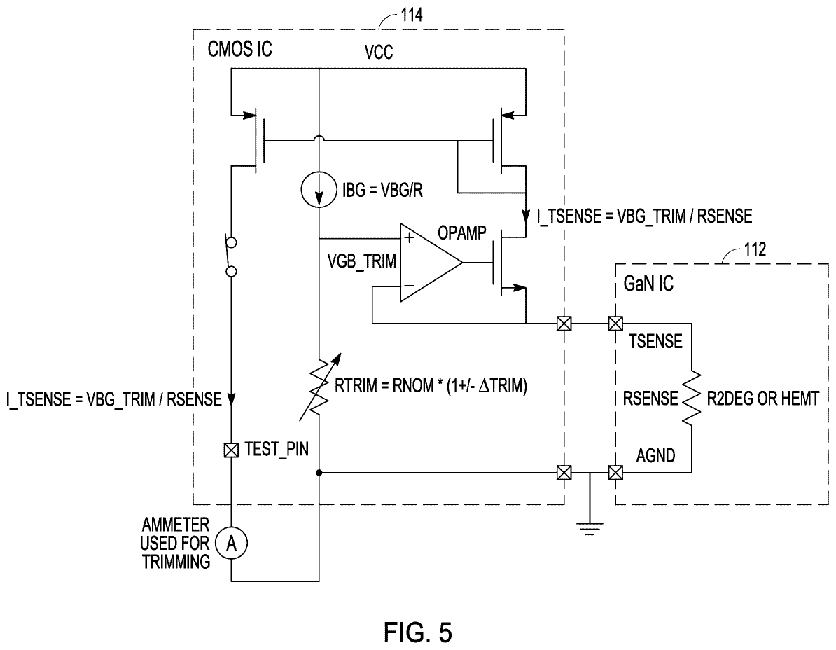

FIG. 5 is an example of using the circuit of FIG. 2 to compensate for process variations in the resistance of the 2DEG channel. In the example of FIG. 5, the bandgap reference voltage VBG_trim is trimmed using trim resistor Rtrim. The reference voltage is trimmed to produce an expected sense current I_TSENSE current at the trim temperature. Trimming the reference voltage compensates for the process variation in resistance of the 2DEG channel so that the variation in sense current is the same between devices over the same range of temperature. At the trimming temperature, the trimmed voltage is

$$VBG\_trim = VBG * Rtrim / R ,$$

and the sense current is

$$I\_TSENSE = VBG\_trim / RSENSE .$$

The mirrored current of the sense current can be measured externally at the test pin during a test mode and the trim resistance Rtrim can be varied until the sensed current is equal to the desired nominal value at the trim temperature

$$Rtrim = Rnom * ( 1 \pm Δ trim ) .$$

The sense current is

$$I\_TSENSE = * \frac{( \frac{V B G}{R b g} ) * R n o m * ( 1 \pm Δ trim )}{( R 2 deg * ( 1 \pm Δ process ) * ( 1 + Tempco * T ) )} ,$$

After trimming, Δtrim˜Δprocess, and

$$I\_TSENSE = \frac{( \frac{V B G}{R b g} ) * R n o m}{( R 2 deg * ( 1 + Tempco * T ) )} .$$

It can be seen in the equation that the sense current is inversely proportional to temperature after trimming.

Returning to FIG. 2, during sensing of the 2DEG channel resistance a mirrored current of the sense current is applied to a resistor having a zero-temperature coefficient R_0tempco to produce a sense voltage VSENSE. The sensing circuit can include a comparator 246 to compare the VSENSE to a voltage corresponding to a high temperature threshold. When VSENSE exceeds the threshold the controller 242 may take corrective action.

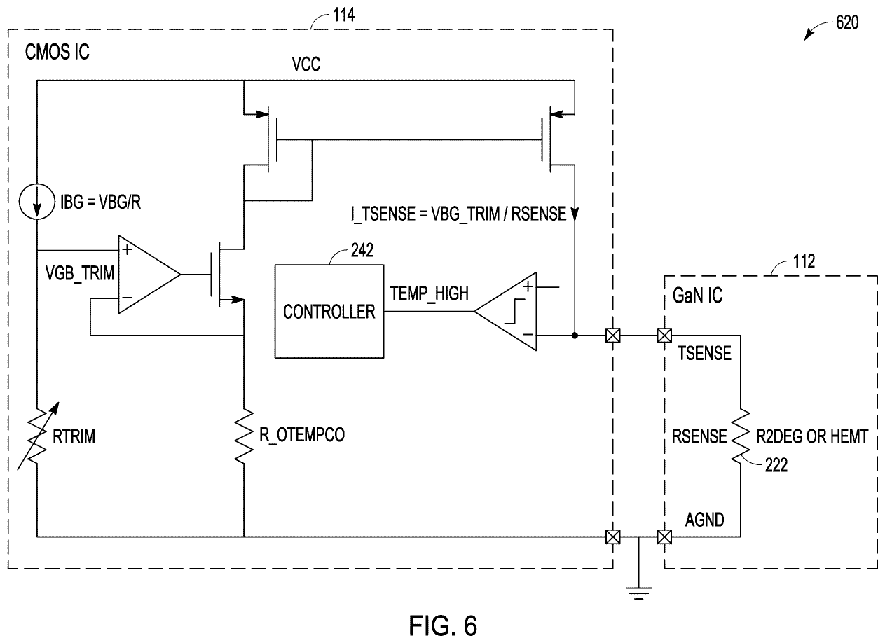

FIG. 6 is a circuit diagram of another example of a temperature sensor circuit 620 to monitor the temperature of GaN power devices. The sensing circuit applies a known current to the temperature sensitive 2DEG channel and measures the resulting voltage to determine the resistance of the 2DEG channel. The temperature sensitive 2DEG channel may be included in a R2DEG resistor 222 or may be included in a measurement HEMT.

It should be noted that the temperature detection is not dependent on the temperature of the separate CMOS IC die 114. Placing the temperature sensitive 2DEG channel device close to the power devices in the GaN IC die 112 in layout allows for accurate measurement of the junction temperature of GaN devices in the GaN IC die including the HEMT power devices. The controller 242 takes corrective action to avoid damage to the power devices.

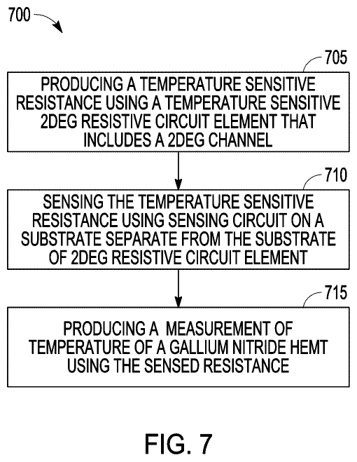

For completeness, FIG. 7 is a flow diagram of a method 700 of monitoring temperature of at least one GaN HEMT that is a switching circuit element of a switching regulator circuit. At block 705, a temperature sensitive resistance is produced using a temperature sensitive 2DEG resistive circuit element that includes a 2DEG channel. The GaN HEMT and the temperature sensitive 2DEG resistive circuit element are included on the same substrate of the same IC die. The temperature sensitive 2DEG resistive circuit may be a 2DEG channel resistor included in the IC die and arranged near the HEMT or HEMTs to be monitored. In some examples, the temperature sensitive 2DEG resistive circuit element is a measurement HEMT that includes the 2DEG channel and is arranged near the HEMT or HEMTs to be monitored. The measurement HEMT may be a D-Mode HEMT or an E-Mode HEMT.

At block 710, the temperature sensitive resistance is sensed using a sensing circuit of a substrate of another IC die that is different from the substrate containing the HEMT and the temperature sensitive 2DEG resistive circuit element. In some examples, the separate IC die is formed using a CMOS process. At block 715, a measurement of temperature of the GaN HEMT is produced using the sensed temperature sensitive resistance.

To sense the resistance of the 2DEG channel, the sensing circuit may generate a known zero temperature coefficient voltage and apply the voltage to the 2DEG channel resistor to produce a temperature sensitive sense current. In certain examples, the sensing circuit includes a bandgap voltage reference and produces the voltage applied to the 2DEG channel using the bandgap voltage reference. A controller (e.g., the controller 242 in FIG. 2) determines a measure of temperature of the HEMT using the temperature sensitive current. In certain examples, a temperature sensitive voltage is produced, and the controller determines the measure of temperature of the HEMT using the temperature sensitive voltage. The temperature sensitive voltage may be generated by applying the temperature sensitive current to a zero-temperature coefficient resistor. When the measured temperature exceeds a predetermined temperature, corrective action may be taken (e.g., by the controller), to slow operation of the HEMT or halt operation of the HEMT. In some examples, the GaN IC die includes multiple temperature sensitive 2DEG resistive circuit elements. The other IC die can include multiple sensing circuits to sense the temperature of the circuit elements, or the other IC die can include one sensing circuit switchable to apply a measuring voltage or current to the multiple temperature sensitive 2DEG resistive circuit elements. The controller may average the measured temperatures to determine the temperature of the GaN IC die.

The devices, systems and methods described herein provide techniques to monitor the junction temperature of GaN power switching devices using circuits of an IC that is not GaN. A temperature sensitive GaN circuit element monitors the temperature of the GaN power switching devices, and an indication of temperature is monitored using the IC that is not GaN. This allows flexibility in the design of the circuits that monitor temperature of the GaN power switching devices.

### ADDITIONAL DESCRIPTION AND ASPECTS

A first Aspect (Aspect 1) includes subject matter (such as a temperature sensing circuit) comprising a gallium nitride (GaN) integrated circuit (IC) die including a temperature sensitive two-dimensional electron gas (2DEG) resistive circuit element that includes a 2DEG channel, and a sensing circuit configured to sense resistance of the temperature sensitive 2DEG resistive circuit element.

In Aspect 2, the subject matter of Aspect 1 optionally includes the sensing circuit is included in a separate IC die. In certain aspects, the separate IC die is formed using a complementary metal oxide semiconductor (CMOS) process and the sensing circuit includes CMOS circuit elements.

In Aspect 3, the subject matter of one or both of Aspects 1 and 2 optionally includes a 2DEG channel resistor as the temperature sensitive 2DEG resistive circuit element.

In Aspect 4, the subject matter of one or both of Aspects 1 and 2 optionally includes a 2DEG channel of a depletion mode high electron mobility transistor (D-Mode HEMT) as the temperature sensitive 2DEG resistive circuit element.

In Aspect 5, the subject matter of one or both of Aspects 1 and 2 optionally includes a 2DEG channel of an enhancement mode high electron mobility transistor (E-Mode HEMT) as the temperature sensitive 2DEG resistive circuit element.

In Aspect 6, the subject matter of one or any combination of Aspects 1-5 optionally includes the sensing circuit included in a separate IC die from the GaN IC die. The sensing circuit includes a zero-temperature coefficient voltage reference to apply a known voltage to the temperature sensitive 2DEG resistive circuit element of the GaN IC die, and a current sensing circuit to determine a temperature sensitive sense current produced by applying the known voltage.

In Aspect 7, the subject matter of Aspect 6 optionally includes the sensing circuit of the separate IC die including a zero-temperature coefficient resistor to produce a temperature sensitive sense voltage using the temperature sensitive sense current.

In Aspect 8, the subject matter of one or both of Aspects 6 and 7 optionally includes a trim circuit configured to trim the temperature sensitive sense current to a predetermined current value at a predetermined temperature.

In Aspect 9, the subject matter of one or any combination of Aspects 1-8 optionally includes the sensing circuit including a zero-temperature coefficient current reference to apply a known current to the temperature sensitive 2DEG resistive circuit element of the GaN IC, and a voltage sensing circuit to determine a temperature sensitive sense voltage produced by applying the known current.

In Aspect 10, the subject matter of Aspect 9 optionally includes a trim circuit configured to trim the temperature sensitive sense voltage to a predetermined voltage value at a predetermined temperature.

Aspect 11 includes subject matter (such as a temperature monitoring system) or can optionally be combined with one or any combination of Aspects 1-10 to include such subject matter, a temperature sensitive two-dimensional electron gas (2DEG) resistive circuit element that includes a 2DEG channel, and a sensing circuit configured to sense a change in resistance with temperature of the temperature sensitive 2DEG resistive circuit element of the first substrate.

In Aspect 12, the subject matter of Aspect 11 optionally includes a 2DEG channel resistor as the temperature sensitive 2DEG resistive circuit element, and the sensing circuit includes complementary metal oxide semiconductor (CMOS) circuit elements.

In Aspect 13, the subject matter of Aspect 11 optionally includes a 2DEG channel of a depletion mode high electron mobility transistor (D-Mode HEMT) as the temperature sensitive 2DEG resistive circuit element, and the sensing circuit includes CMOS circuit elements.

In Aspect 14, the subject matter of Aspect 11 optionally includes a 2DEG channel of an enhancement mode high electron mobility transistor (D-Mode HEMT) as the temperature sensitive 2DEG resistive circuit element, and the sensing circuit includes CMOS circuit elements.

In Aspect 15, the subject matter of one or any combination of Aspects 11-14 optionally includes a bandgap voltage reference that includes a bipolar junction transistor (BJT), and a sensing circuit configured to produce a known zero temperature coefficient voltage using the bandgap voltage reference, apply the known zero temperature coefficient voltage to the temperature sensitive 2DEG resistive circuit element, and determine a temperature sensitive sense current produced by applying the known voltage.

In Aspect 16, the subject matter of one or any combination of Aspects 11-15 optionally includes a zero-temperature coefficient current reference to apply a known current to the temperature sensitive 2DEG resistive circuit element, and a voltage sensing circuit to determine a temperature sensitive sense voltage produced by applying the known current to the temperature sensitive 2DEG resistive circuit element.

In Aspect 17, the subject matter of one or any combination of Aspects 11-16 optionally includes a controller operatively coupled to the sensing circuit of the second substrate, the first substrate including multiple temperature sensitive 2DEG resistive circuit elements, and a sensing circuit configured to monitor resistances of the multiple temperature sensitive 2DEG resistive circuit elements. The controller is optionally configured to determine temperature of the first substrate using the resistances of the multiple temperature sensitive 2DEG resistive circuit elements.

In Aspect 18, the subject matter of Aspect 17 optionally includes a first substrate including a switching circuit element of a switching regulator circuit, wherein the switching circuit element includes a gallium nitride (GaN) high electron mobility transistor (HEMT), and a second substrate including a pulse width modulation (PWM) controller of the switching regulator circuit.

Aspect 19 includes subject matter (such as method of monitoring temperature of a GaN HEMT that is a switching circuit element of a switching regulator circuit) or can optionally be combined with one or any combination of Aspects 1-18 to include such subject matter, comprising producing a temperature sensitive resistance using a temperature sensitive 2DEG resistive circuit element that includes a 2DEG channel; sensing the temperature sensitive resistance using a sensing circuit; and producing a measurement of temperature of the GaN HEMT using the sensed temperature sensitive resistance.

In Aspect 20, the subject matter of Aspect 19 optionally includes producing the temperature sensitive using a 2DEG channel resistor, producing a known zero temperature coefficient voltage using a bipolar junction transistor (BJT), and applying the known zero temperature coefficient voltage to the 2DEG channel resistor to produce a temperature sensitive sense current.

The non-limiting Aspects can be combined in any permutation or combination. Each of the non-limiting aspects described in this document can stand on its own or can be combined in various permutations or combinations with one or more of the other aspects or other subject matter described in this document.

The above detailed description includes references to the accompanying drawings, which form a part of the detailed description. The drawings show, by way of illustration, specific embodiments in which the invention can be practiced. These embodiments are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following aspects, the terms “including” and “comprising” are open-ended, that is, a system, device, article, composition, formulation, or process that includes elements in addition to those listed after such a term in a claim are still deemed to fall within the scope of that claim. Moreover, in the following aspects, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following aspects are hereby incorporated into the Detailed Description as examples or embodiments, with each aspect standing on its own as a separate embodiment, and it is contemplated that such embodiments can be combined with each other in various combinations or permutations.

What is claimed is:

1. A temperature sensor circuit comprising:
a gallium nitride (GaN) integrated circuit (IC) die including a temperature sensitive two-dimensional electron gas (2DEG) resistive circuit element that includes a 2DEG channel; and
a sensing circuit configured to sense resistance of the temperature sensitive 2DEG resistive circuit element.

2. The temperature sensor circuit of claim 1, wherein the sensing circuit is included in a separate IC die formed using a complementary metal oxide semiconductor (CMOS) process and the sensing circuit includes CMOS circuit elements.

3. The temperature sensor circuit of claim 1, wherein the temperature sensitive 2DEG resistive circuit element is a 2DEG channel resistor.

4. The temperature sensor circuit of claim 1, wherein the temperature sensitive 2DEG resistive circuit element is a 2DEG channel of a depletion mode high electron mobility transistor (D-Mode HEMT).

5. The temperature sensor circuit of claim 1, wherein the temperature sensitive 2DEG resistive circuit element is a 2DEG channel of an enhancement mode high electron mobility transistor (E-Mode HEMT).

6. The temperature sensor circuit of claim 1, wherein the sensing circuit is included in a separate IC die and the sensing circuit includes:
a zero-temperature coefficient voltage reference to apply a known voltage to the temperature sensitive 2DEG resistive circuit element of the GaN IC die; and
a current sensing circuit to determine a temperature sensitive sense current produced by applying the known voltage.

7. The temperature sensor circuit of claim 6, wherein the sensing circuit of the separate IC die includes:
a zero-temperature coefficient resistor to produce a temperature sensitive sense voltage using the temperature sensitive sense current.

8. The temperature sensor circuit of claim 6, including a trim circuit configured to trim the temperature sensitive sense current to a predetermined current value at a predetermined temperature.

9. The temperature sensor circuit of claim 1, wherein the sensing circuit is included in a separate IC die and the sensing circuit includes:
a zero-temperature coefficient current reference to apply a known current to the temperature sensitive 2DEG resistive circuit element of the GaN IC die; and
a voltage sensing circuit to determine a temperature sensitive sense voltage produced by applying the known current.

10. The temperature sensor circuit of claim 9, including a trim circuit configured to trim the temperature sensitive sense voltage to a predetermined voltage value at a predetermined temperature.

11. A temperature monitoring system, the system comprising:
a temperature sensitive two-dimensional electron gas (2DEG) resistive circuit element that includes a 2DEG channel; and
a sensing circuit configured to sense a change in resistance with temperature of the temperature sensitive 2DEG resistive circuit element.

12. The system of claim 11, wherein the temperature sensitive 2DEG resistive circuit element is a 2DEG channel resistor, and the sensing circuit includes complementary metal oxide semiconductor (CMOS) circuit elements.

13. The system of claim 11, wherein the temperature sensitive 2DEG resistive circuit element is a 2DEG channel of a depletion mode high electron mobility transistor (D-Mode HEMT), and the sensing circuit includes CMOS circuit elements.

14. The system of claim 11, wherein the temperature sensitive 2DEG resistive circuit element is a 2DEG channel of an enhancement mode high electron mobility transistor (E-Mode HEMT), and the sensing circuit includes CMOS circuit elements.

15. The system of claim 11, including:
a bandgap voltage reference that includes a bipolar junction transistor (BJT); and
wherein the sensing circuit is configured to:
produce a known zero temperature coefficient voltage using the bandgap voltage reference;
apply the known zero temperature coefficient voltage to the temperature sensitive 2DEG resistive circuit element; and
determine a temperature sensitive sense current produced by applying the known voltage.

16. The system of claim 11, including:
a zero-temperature coefficient current reference to apply a known current to the temperature sensitive 2DEG resistive circuit element; and
a voltage sensing circuit to determine a temperature sensitive sense voltage produced by applying the known current to the temperature sensitive 2DEG resistive circuit element.

17. The system of claim 11, including:
multiple temperature sensitive 2DEG resistive circuit elements included on a first substrate;
a controller operatively coupled to the sensing circuit;
wherein the sensing circuit is included on a second substrate and is configured to monitor resistances of the multiple temperature sensitive 2DEG resistive circuit elements; and
wherein the controller is configured to determine temperature of the first substrate using the resistances of the multiple temperature sensitive 2DEG resistive circuit elements.

18. The system of claim 17,
wherein the first substrate includes a switching circuit element of a switching regulator circuit, wherein the switching circuit element includes a gallium nitride (GaN) high electron mobility transistor (HEMT); and
wherein the second substrate includes a pulse width modulation (PWM) controller of the switching regulator circuit.

19. A method of monitoring temperature of a gallium nitride (GaN) high electron mobility transistor (HEMT) that is a switching circuit element of a switching regulator circuit, the method comprising:
producing a temperature sensitive resistance using a temperature sensitive two-dimensional electron gas (2DEG) resistive circuit element that includes a 2DEG channel;
sensing the temperature sensitive resistance using a sensing circuit; and
producing a measurement of temperature of the GaN HEMT using the sensed temperature sensitive resistance.

20. The method of claim 19,
wherein the producing the temperature sensitive resistance includes producing the temperature sensitive using a 2DEG channel resistor, and
wherein the sensing the temperature sensitive resistance includes:
producing a known zero temperature coefficient voltage using a bipolar junction transistor (BJT); and
applying the known zero temperature coefficient voltage to the 2DEG channel resistor to produce a temperature sensitive sense current.
